(19) United States
(12) Patent Application Publication
(10) Pub. No.: US 2013/0140664 A1
(43) Pub. Date: Jun. 6, 2013

(54) FLIP CHIP PACKAGING STRUCTURE

(71) Applicants: JUI-HSIANG LO, New Taipei (TW); Tsung-shih Lee, New Taipei (TW)

(72) Inventors: JUI-HSIANG LO, New Taipei (TW); Tsung-shih Lee, New Taipei (TW)

(73) Assignee: Cheng Uei Precision Industry Co., LTD., New Taipei City (TW)

(21) Appl. No.: 13/310,703

(22) Filed: Dec. 2, 2011

(51) Int. Cl. H01L 31/02

(52) U.S. Cl. 257/443; 257/E31.113

(57) ABSTRACT

The present invention discloses a flip chip packaging structure which is applied to a process of a compact camera module (CCM), and the structure thereof comprises an image sensor component, at least one connection member, a circuit board and an insulating plate. The image sensor component is electrically connected with the circuit board via an electrical-conduction of the connection body. Hence, by disposing the insulating plate between the image sensor component and the circuit board, the present invention not only can provide a thermal insulating protection to the image sensor component but also use enough space to execute a surface mount technology (SMT), so as to simplify the flip chip process and to increase the yield of manufacture.

### BACKGROUND OF THE INVENTION

1. Field of the Invention

The present invention relates to a flip chip packaging structure, and in particular to a flip chip packaging structure which uses a surface mount technology (SMT) to simplify a packaging process of a compact camera module (CCM).

2. The Related Arts

Referring now to FIG. 1, a structure of a compact camera module (CCM) 2 using a traditional technology is illustrated in FIG. 1. The structure comprises a circuit board 35, an image sensor component 12, solder balls 14, a covering member 16, a covering plate 18, a lens housing 22 and a lens 20, wherein the image sensor component 12 needs to be packaged because it further needs to be connected with other elements, such as a heat sink or a protecting shell. Recently, there are various types of packages and the request for accuracy of processes is higher day by day. Moreover, for reducing the manpower cost, it is necessary to utilize automation and the non-welding-wire technology. Hence, the packaging technologies are changed from the old packaging types, such as the Dual Inline Package (DIP) and the Quad Flat Package (QFP), to the new packaging types, such as the Ball Grid Array (BGA) and the Flip Chip (FC). Because the packaging type of flip chip can solve the problem of the size caused by that the bonding wires is too large, the various types of the flip chip packaging technologies which applied to different products are developed, wherein most of them need to use electro-conductive bumps of the flip chip packaging technology to achieve the object for the package connection.

The traditional process of the flip chip packaging technology comprises three basic steps, as follows: the first step is to wash a surface of electro-conductive bumps and remove an oxide layer from it; the second step is to reflow soldering; and the third step is a subsequent wash, wherein the reflow step is very important. In the reflow step, the reheated connection agent must be freely flowed among welding pads, the electro-conductive bumps and conductive circuits, so as to cause hermetic seal and firm connection. However, the appropriate reflow soldering only happens after the oxide layer with a high melting point is removed from a to-be-connected surface. Therefore, how to improve the traditional flip chip packaging technology has become a very important issue when manufacturers on the surface.

Therefore, there is a need for providing a flip chip packaging structure, to solve existing problems in the conventional technology.

### SUMMARY OF THE INVENTION

To overcome the problem of traditional technology, the present invention provides a flip chip packaging structure, which not only provides a thermal insulating protection to the image sensor component but also uses the surface mount technology (SMT), so as to simplify the flip chip process of a compact camera module (CCM), and to increase the yield of manufacture.

To achieve the above objective, the present invention provides a flip chip packaging structure comprises an image sensor component, at least one connection member, a circuit board and an insulating plate.

The image sensor component has an active surface and an inactive surface, wherein the inactive surface is provided with at least one welding pad to electrically connect with the image sensor component, and the active surface is used to capture images. The above mentioned image sensor component can be a normal integrated circuit component.

The circuit board comprises a metal circuit layer and a substrate, and the substrate has a substrate surface for disposing the metal circuit layer. The above mentioned substrate can be made of a ceramic substrate, a polymeric substrate or a FR4 material layer.

The insulating plate is attached onto the inactive surface of the image sensor component, so that the inactive surface of the image sensor component keeps a predetermined gap with the circuit board, so as to isolate the heat from the circuit board. The insulating plate can be made of infrared filter or mica sheet.

The at least one connection body is disposed between the image sensor component and the circuit board, and is corresponding to the at least one welding pad. Besides, the connection member further comprises at least one first electric conducting structure, such as electro-conductive bump, and at least one second electric conducting structure, such as welding/connection material. By the electrical connection between the at least one first electric conducting structure and the at least one second electric conducting structure, it can further carry out the electrical connection between the image sensor component and the circuit board.

According to one preferred embodiment of the present invention, the at least one first electric conducting structure is disposed on the welding pad of the image sensor component, and electrically connected with the welding pad; one part of the at least one second electric conducting structure is attached to a surface of the at least one first electric conducting structure so as to be electrically connected thereto; and the other part of the second electric conducting structure is disposed on the metal circuit layer.

According to another preferred embodiment of the present invention, the at least one first electric conducting structure is disposed on the metal circuit layer, and electrically connect with the metal circuit layer; one part of the at least one second electric conducting structure is attached to a surface of the at least one first electric conducting structure so as to electrically connect thereto; and the other part of the second electric conducting structure is disposed on the welding pad of the image sensor component.

The insulating plate is attached onto the inactive surface of the image sensor component to isolate the heat from the metal circuit layer of the circuit board, so that the inactive surface of the image sensor component keeps a predetermined gap with the circuit board.

As described above, by using the insulating plate, the present invention makes the inactive surface of the image sensor component keep a predetermined gap with the circuit board. It not only can provide an insulating protection to the image sensor component but also use the surface mount technology (SMT) to simplify the flip chip process, and it is unnecessary to be manufactured in the dust-free room, so that a pollution of particle can be lowered and the yield of the process of the flip chip packaging structure can be increased.

### BRIEF DESCRIPTION OF THE DRAWINGS

The present invention will be apparent to those skilled in the art by reading the following description of a preferred embodiment of the present invention, with reference to the attached drawings, in which:

FIG. 1 is a structural schematic view showing a traditional compact camera module;

FIG. 2a is an exploded view of components of a flip chip packaging structure according to the present invention;

FIG. 2b is an assembled view of components of the flip chip packaging structure according to the present invention;

FIG. 3a is a structural schematic view showing a connection member of the flip chip packaging structure;

FIG. 3b is a structural schematic view showing another connection member of the flip chip packaging structure; and

FIGS. 4a to 4d are schematic views of steps of the flip chip packaging structure according to the present invention.

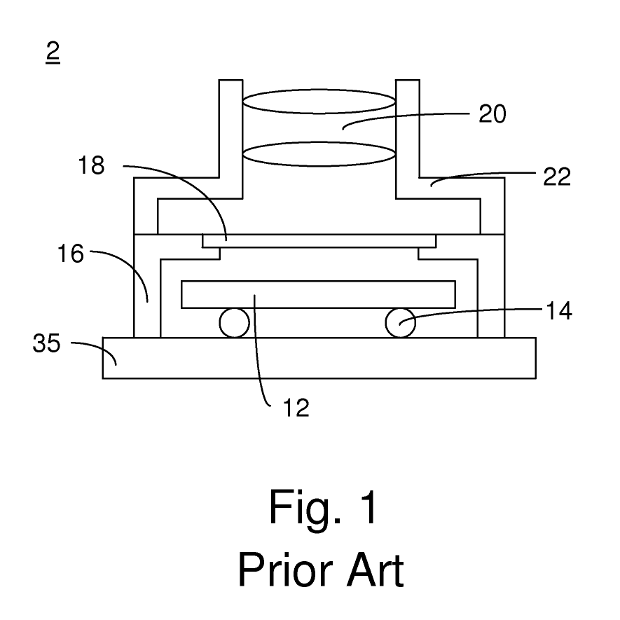

### DETAILED DESCRIPTION OF THE PREFERRED EMBODIMENT

The foregoing objects, features and advantages adopted by the present invention can be best understood by referring to the following detailed description of the preferred embodiments and the accompanying drawings. It should be noted that, the numerals in different drawings means the same or similar terms; the surface directional definition of the following mentioned accompanying drawings is perpendicular to the normal vector of the surface, and the directional terms described in the present invention are only used to describe and understand the present invention, but the present invention is not limited thereto.

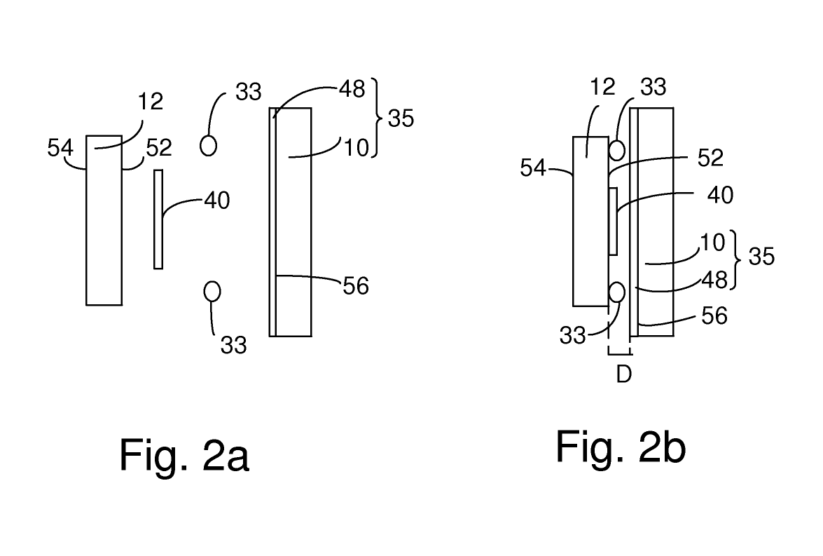

Referring now to FIGS. 2a and 2b, a flip chip packaging structure according to a preferred embodiment of the present invention is illustrated in FIGS. 2a and 2b. The flip chip packaging structure is applied to a process of a compact camera module (CCM), and the structure thereof comprises an image sensor component 12, a plurality of connection members 33, a circuit board 35 and an insulating plate 40.

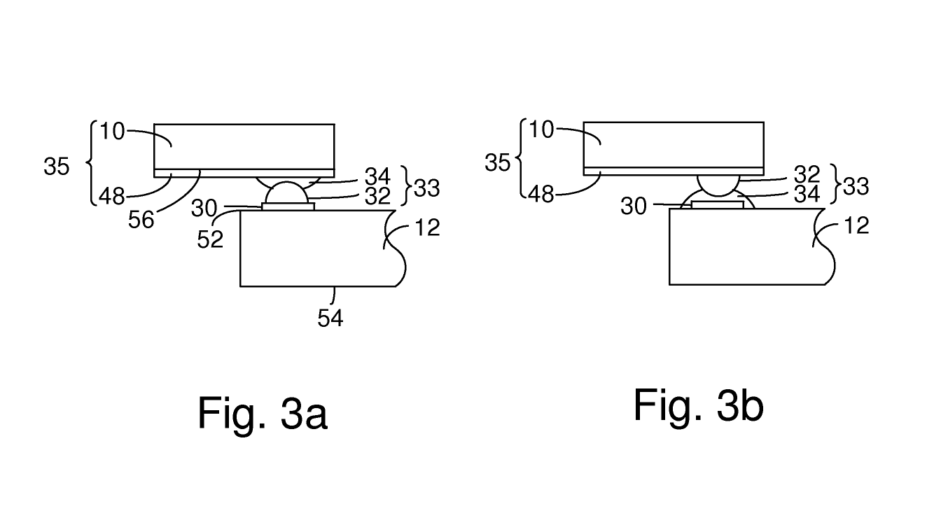

The image sensor component 12 has an inactive surface 52 and an active surface 54, both of which are corresponding to each other, wherein the inactive surface 52 is provided with at least one welding pad 30, as shown in FIGS. 3a and 3b, which is used to electrically connect with the image sensor component 12, and the active surface 54 is used to capture images through the image sensor component 12. It should be noted that, although the flip chip packaging structure of the preferred embodiment is the image sensor component 12, the present invention is not limited thereto; in other preferred embodiments, it can be other integrated circuits (ICs). Embodiments of other integrated circuits (ICs) also can be included in the present invention. Because the applications of the other embodiments are the same as this preferred embodiment, they are omitted to avoid repetition.

The circuit board 35 is constructed by a substrate 10 and a metal circuit layer 48, wherein the substrate 10 has a substrate surface 56 for disposing the metal circuit layer 48, and the metal circuit layer 48 has a plurality of distributed metal tracing lines. The above mentioned substrate 10 can be a ceramic substrate or a polymeric substrate which are suitably applied to a process of flip chip which is easy to dissipate heat and have a smooth surface, or can be made of the material of normal glass fiber (FR4 material layer) to lower the cost.

As shown in FIG. 2b, the insulating plate 40 is disposed between the image sensor component 12 and the circuit board 35, and especially it is attached onto the inactive surface 52 of the image sensor component 12, so as to be arranged on the same plane which the connection members 33 are disposed on. By above mention, it can isolate the heat from the metal circuit layer 48 of the circuit board 35 so as to protect the image sensor component 12, and to keep a predetermined gap “D” between the inactive surface 52 of the image sensor component 12 and the metal circuit layer 48. Besides, the insulating plate 40 can be made of infrared (IR) filter or mica sheet.

Further referring now to FIGS. 3a, in a preferred embodiment of the present invention, each of the connection members 33 is disposed between the image sensor component 12 and the circuit board 35, and is corresponding to the at least one welding pad 30. Besides, the connection member 33 further comprises at least one first electric conducting structure 32, such as electro-conductive bump, and at least one second electric conducting structure 34 which can be made of welding/connection material. As above mentioned, the first electric conducting structure 32 can be made of metal material with good electro-conductivity, such as gold, copper and the alloy thereof, and the welding/connection material of the second electric conducting structure 34 can be made of electro-conducting material with good soldering effect, such as solder, solder paste or silver adhesive/paste.

The bottom of the at least one first electric conducting structure 32 is disposed on the welding pad 30 of the image sensor component 12 and is used to electrically connect with the welding pad 30. Besides, one part of the at least one second electric conducting structure 34 is attached to a protruded surface of an apex of the at least one first electric conducting structure 32 so as to electrically connect thereto. Moreover, the other part of the second electric conducting structure 34 is disposed on the metal circuit layer 48 of the circuit board 35 so as to electrically connect with some metal tracing lines of the metal circuit layer 48. By the electrical connection between the at least one first electric conducting structure 32 and the at least one second electric conducting structure 34, it can further conduct the electrical connection between the image sensor component 12 and the circuit board 35.

Referring now to FIGS. 3b in addition, a flip chip packaging structure according to another embodiment of the present invention is illustrated in FIG. 3b. In comparison with the embodiment shown in FIG. 3a, the difference of this embodiment is that: the disposition of the at least one first electric conducting structure 32 is opposite to the disposition of the at least one second electric conducting structure 34. In the FIG. 3b, the bottom of the at least one first electric conducting structure 32 is disposed on the metal circuit layer 48 of the circuit board 35, so as to electrically connect with the metal tracing lines of the metal circuit layer 48. Moreover, one part of the at least one second electric conducting structure 34 is attached to a protruding surface of an apex of the at least one first electric conducting structure 32, so as to electrically connect thereto; and the other part thereof is disposed on the welding pad 30 of the image sensor component 12 so as to electrically connect with the welding pad 30. Similarly, by the electrical connection between the at least one first electric conducting structure 32 and the at least one second electric conducting structure 34, it also can carry out the electrical connection between the image sensor component 12 and the circuit board 35.

As the description in the prior art, in the process of the flip chip packaging technology, the step of the reflow soldering is very important. For increasing the realization, the applications of the present invention are described by embodiments of FIGS. 2b and 3a. The present invention keeps a predetermined gap “D” between the inactive surface 52 of the image sensor component 12 and the metal circuit layer 48 by using the insulating plate 40. By above mentioned, it is not only makes that the reheated second electric conducting structure 34 can freely flow between the welding pad 30 of the image sensor component 12 and the metal circuit layer 48 of the circuit board 35, so as to cause hermetic seal and firm connection, but also can provide a thermal insulating protection to the image sensor component 12, so as to increase the yield of the flip chip packaging process. Besides, because the space is enough, it can use the surface mount technology (SMT) to manufacture, so as to simplify the flip chip packaging process, and prevent from a pollution of particle, so that it is unnecessary to be manufactured in the dust-free room.

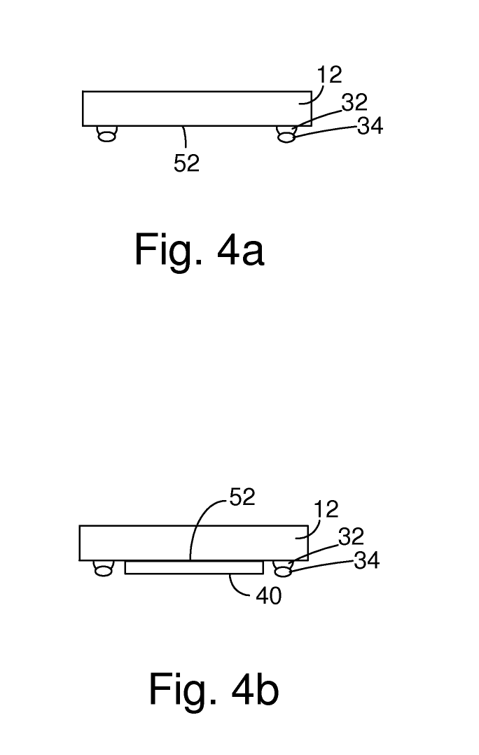

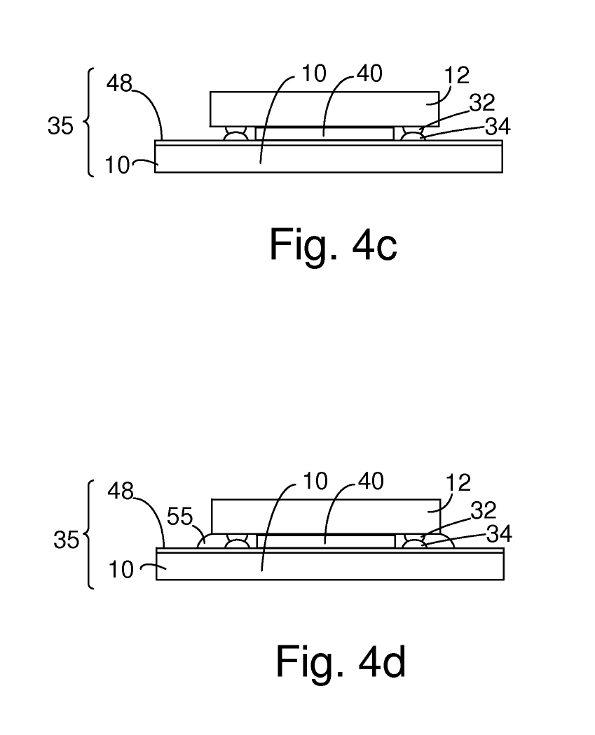

As above mentioned, referring now to FIGS. 4a to 4d, a process of the flip chip packaging structure according to the present invention is illustrated in FIGS. 4a to 4d.

Firstly, as shown in FIG. 4a, the inactive surface 52 of the image sensor component 12 has a plurality of the first electric conducting structures 32, and the surface of each first electric conducting structure 32 is attached with a corresponding second electric conducting structure 34; secondly, referring to FIG. 4b, the inactive surface 52 of the image sensor component 12 is attached with a insulating plate 40; then, as shown in FIG. 4c, the second electric conducting structure 34 and insulating plate 40 are connected to the metal tracing lines of the conducting wire layer 48 of the circuit board 35; Finally, as shown in FIG. 4d, a solder 55 is added among the first electric conducting structure 32, the second electric conducting structure 34 and the metal circuit layer 48, and to heat the solder 55 by using a surface mount technology (SMT), so as to firmly connect the second electric conducting structure 34 with the metal circuit layer 48, and to achieve the electric connection between the image sensor component 12 and the circuit board 35. Thus, it can simplify the process and increase the yield rate.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A flip chip packaging structure, comprising:
an image sensor component having an active surface and an inactive surface, wherein the inactive surface is provided with at least one welding pad to electrically connect with the image sensor component, and the active surface is used to capture images;
a circuit board corresponding to the image sensor component;
an insulating plate attached onto the inactive surface of the image sensor component, so that the inactive surface of the image sensor component keeps a predetermined gap with the circuit board to isolate the heat from the circuit board; and
at least one first electric conducting structure and at least one second electric conducting structure, both of which are disposed between the image sensor component and the circuit board and corresponding to the welding pad;
wherein the electrical connection between the at least one first electric conducting structure and the at least one second electric conducting structure causes the electrical connection between the image sensor component and the circuit board.

2. The flip chip packaging structure as claimed in claim 1, wherein the image sensor component is an integrated circuit component.

3. The flip chip packaging structure as claimed in claim 1, wherein the circuit board further comprises a metal circuit layer and a substrate, and the substrate has a substrate surface for disposing the metal circuit layer.

4. The flip chip packaging structure as claimed in claim 3, wherein the at least one first electric conducting structure is disposed on the welding pad of the image sensor component and electrically connected with the welding pad; one part of the at least one second electric conducting structure is attached to a surface of the at least one first electric conducting structure so as to be electrically connected thereto; and the other part of the second electric conducting structure is disposed on the metal circuit layer so as to be electrically connected with the metal circuit layer.

5. The flip chip packaging structure as claimed in claim 3, wherein the at least one first electric conducting structure is disposed on the metal circuit layer and electrically connected with the metal circuit layer; one part of the at least one second electric conducting structure is attached to a surface of the at least one first electric conducting structure so as to be electrically connected thereto; and the other part of the second electric conducting structure is disposed on the welding pad of the image sensor component so as to be electrically connected with the welding pad.

6. The flip chip packaging structure as claimed in claim 1, wherein the at least one first electric conducting structure and the at least one second electric conducting structure are combined into a connection member, and the connection member is disposed on the same plane which the insulating plate is disposed on.

7. The flip chip packaging structure as claimed in claim 3, wherein the substrate is made of a ceramic substrate, a polymeric substrate or a FR4 material layer.

8. The flip chip packaging structure as claimed in claim 1, wherein the insulating plate is made of an infrared filter or a mica sheet.
